(19) United States
(12) Patent Application Publication
(10) Pub. No.: US 2003/0163643 A1
(43) Pub. Date: Aug. 28, 2003

(54) Bank conflict determination

(76) Inventors: Reid James Riedlinger, Fort Collins, CO (US); Dean A. Mulla, Saratoga, CA (US); Tom Grutkowski, Fort Collins, CO (US)

Correspondence Address: HEWLETT-PACKARD COMPANY, Intellectual Property Administration, P.O. Box 272400, Fort Collins, CO, 80527-2400, US

(21) Appl. No.: 10/080,985

(22) Filed: Feb. 22, 2002

(51) Int. Cl. G11C 5/00

(52) U.S. Cl. 711/131; 711/5; 711/128; 711/210

(57) ABSTRACT

A system and method are disclosed which enable resolution of conflicts between memory access requests in a manner that allows for efficient usage of cache memory. In one embodiment, a circuit comprises a cache memory structure comprising multiple banks, and a plurality of access ports communicatively coupled to such cache memory structure. The circuit further comprises circuitry operable to determine a bank conflict for pending access requests for the cache memory structure, and circuitry operable to issue at least one access request to the cache memory structure out of the order in which it was requested, responsive to determination of a bank conflict.

### CROSS-REFERENCE TO RELATED APPLICATIONS

This application is related to co-pending and commonly assigned U.S. patent application Ser. No. 09/510,973 entitled “MULTILEVEL CACHE STRUCTURE AND METHOD USING MULTIPLE ISSUE ALGORITHM WITH OVER SUBSCRIPTION AVOIDANCE FOR HIGH BANDWIDTH CACHE PIPELINE” filed Feb. 21, 2000, co-pending and commonly assigned U.S. patent application Ser. No. 09/510,283 entitled “CACHE CHAIN STRUCTURE TO IMPLEMENT HIGH BANDWIDTH LOW LATENCY CACHE MEMORY SUBSYSTEM” filed Feb. 21, 2000, co-pending and commonly assigned U.S. patent application Ser. No. 09/510,285 entitled “L1 CACHE MEMORY” filed Feb. 21, 2000, co-pending and commonly assigned U.S. patent application Ser. No. 09/501,396 entitled “METHOD AND SYSTEM FOR EARLY TAG ACCESSES FOR LOWER-LEVEL CACHES IN PARALLEL WITH FIRST-LEVEL CACHE” filed Feb. 9, 2000, co-pending and commonly assigned U.S. patent application Ser. No. 09/510,279 entitled “CACHE ADDRESS CONFLICT MECHANISM WITHOUT STORE BUFFERS” filed Feb. 21, 2000, co-pending and commonly assigned U.S. patent application Ser. No. 09/507,546 entitled “SYSTEM AND METHOD UTILIZING SPECULATIVE CACHE ACCESS FOR IMPROVED PERFORMANCE” filed Feb. 18, 2000, and co-pending and commonly assigned U.S. patent application Ser. No. 09/507,241 entitled “METHOD AND SYSTEM FOR PROVIDING A HIGH BANDWIDTH CACHE THAT ENABLES SIMULTANEOUS READS AND WRITES WITHIN THE CACHE” filed Feb. 18, 2000, the disclosures of which are hereby incorporated herein by reference.

### BACKGROUND OF THE INVENTION

1. Technical Field

This application relates in general to cache memory subsystems, and in specific to a system and method for efficiently determining and resolving conflicts between memory access requests for cache memory.

2. Background

Computer systems may employ a multi-level hierarchy of memory, with relatively fast, expensive but limited-capacity memory at the highest level of the hierarchy and proceeding to relatively slower, lower cost but higher-capacity memory at the lowest level of the hierarchy. The hierarchy may include a small, fast memory called a cache, either physically integrated within a processor or mounted physically close to the processor for speed. The computer system may employ separate instruction caches and data caches. In addition, the computer system may use multiple levels of caches. The use of a cache is generally transparent to a computer program at the instruction level and can thus be added to a computer architecture without changing the instruction set or requiring modification to existing programs.

Computer processors typically include cache for storing data. When executing an instruction that requires access to memory (e.g., read from or write to memory), a processor typically accesses cache in an attempt to satisfy the instruction. Of course, it is desirable to have the cache implemented in a manner that allows the processor to access the cache in an efficient manner. That is, it is desirable to have the cache implemented in a manner such that the processor is capable of accessing the cache (i.e., reading from or writing to the cache) quickly so that the processor may be capable of executing instructions quickly. Caches have been configured in both on-chip and off-chip arrangements. On-processor-chip caches have less latency because they are closer to the processor, but since on-chip area is expensive, such caches are typically smaller than off-chip caches. Off-processor-chip caches have longer latencies because they are remotely located from the processor, but such caches are typically larger than on-chip caches.

A prior art solution has been to have multiple caches, some small and some large. Typically, the smaller caches would be located on-chip, and the larger caches would be located off-chip. Typically, in multi-level cache designs, the first level of cache (i.e., L0) is first accessed to determine whether a true cache hit (which is described further below) is achieved for a memory access request. If a true cache hit is not achieved for the first level of cache, then a determination is made for the second level of cache (i.e., L1), and so on, until the memory access request is satisfied by a level of cache. If the requested address is not found in any of the cache levels, the processor then sends a request to the system's main memory in an attempt to satisfy the memory access request. In many processor designs, the time required to access an item for a true cache hit is one of the primary limiters for the clock rate of the processor if the designer is seeking a single-cycle cache access time. In other designs, the cache access time may be multiple cycles, but the performance of a processor can be improved in most cases when the cache access time in cycles is reduced. Therefore, optimization of access time for cache hits is critical for the performance of the computer system.

Prior art cache designs for computer processors typically require “control data” or tags to be available before a cache data access begins. The tags indicate whether a desired address (i.e., an address required for a memory access request) is contained within the cache. Accordingly, prior art caches are typically implemented in a serial fashion, wherein upon the cache receiving a memory access request, a tag is obtained for the request, and thereafter if the tag indicates that the desired address is contained within the cache, the cache's data array is accessed to satisfy the memory access request. Thus, prior art cache designs typically generate tags indicating whether a true cache “hit” has been achieved for a level of cache, and only after a true cache hit has been achieved is the cache data actually accessed to satisfy the memory access request. A true cache “hit” occurs when a processor requests an item from a cache and the item is actually present in the cache. A cache “miss” occurs when a processor requests an item from a cache and the item is not present in the cache.

The tag data indicating whether a “true” cache hit has been achieved for a level of cache typically comprises a tag match signal. The tag match signal indicates whether a match was made for a requested address in the tags of a cache level. However, such a tag match signal alone does not indicate whether a true cache hit has been achieved. As an example, in a multi-processor system, a tag match may be achieved for a cache level, but the particular cache line for which the match was achieved may be invalid. For instance, the particular cache line may be invalid because another processor has snooped out that particular cache line. As used herein a “snoop” is an inquiry from a first processor to a second processor as to whether a particular cache address is found within the second processor. Accordingly, in multi-processor systems a MESI signal is also typically utilized to indicate whether a line in cache is “Modified, Exclusive, Shared, or Invalid”. Therefore, the control data that indicates whether a “true” cache hit has been achieved for a level of cache typically comprises a MESI signal, as well as the tag match signal. Only if a tag match is found for a level of cache and the MESI protocol indicates that such tag match is valid, does the control data indicate that a true cache hit has been achieved. In view of the above, in prior art cache designs, a determination is first made as to whether a tag match is found for a level of cache, and then a determination is made as to whether the MESI protocol indicates that a tag match is valid. Thereafter, if a determination has been made that a true tag hit has been achieved, access begins to the actual cache data requested.

As is well known in the art, caches may be partitioned into multiple banks. Further, multiple ports may be implemented for accessing the cache to enable multiple accesses to be performed simultaneously (i.e., in parallel). Typically, in prior art implementations, a queue is included for holding memory accesses that have been determined to be capable of being satisfied by a particular level of cache (e.g., L1 cache) but have not actually been issued to the cache. That is, for one reason or another, cache access requests may not be capable of being immediately issued to the cache, and therefore such requests may be held in a queue until an appropriate time for them to be issued.

As an example, a 256K cache may be divided into 16 banks, and multiple ports for accessing the cache may be implemented (e.g., multiple read and/or write ports). For instance, suppose that four ports are implemented to enable four cache access requests to be satisfied simultaneously in a single clock cycle. Once an access request is received and the bank of the cache capable of satisfying the access is determined (e.g., based on the physical address desired to be accessed), then the access request may be queued. In this exemplary embodiment, four access requests may be issued to the cache simultaneously each clock cycle, i.e., one for each of the four ports of the cache. However, certain access requests cannot properly be issued simultaneously. For example, two access requests for the same bank may result in a conflict.

For instance, suppose a first request pending in the queue desires to write data to a particular bank, and another request pending in the queue simultaneously desires to read data from the same bank. Such requests are in conflict, and a determination must be made as to which order to issue the requests because they cannot properly be issued simultaneously. In other words, conflicts may be present as to the resources desired to be accessed by the pending requests. Generally, the pending request queue is implemented as a first in, first out (FIFO) queue such that the oldest pending request(s) in the queue is/are issued first, and thereafter the newer pending requests are issued in sequential order. Thus, in the above example, it should be recognized that up to four new access requests may be received into the queue each clock cycle, and up to four pending access requests may be issued by the queue each clock cycle.

Prior art methods for resolving bank conflicts between pending requests have generally resulted in inefficient use of the cache, thereby reducing the overall efficiency (and speed) of the processor(s). As one example, prior art implementations have typically not allowed for “out of order processing”. That is, prior art implementations typically utilize a FIFO queue for holding access requests, wherein requests are only issued in the order in which they were received (i.e., from oldest to newest). However, when a bank conflict is encountered between pending requests, such a rigid, in-order method of issuing requests may result in inefficiency within the cache.

As another example of the inefficiency of prior art cache architecture, such architecture is typically implemented to determine whether bank conflicts exist upon actually issuing access requests from the queue to the cache. That is, prior art cache architecture is typically implemented to evaluate the queue of pending requests for access conflicts at the time that the queue is attempting to issue an access request. Such determination of whether a bank conflict exists therefore delays the actual issuance of access requests that are capable of being issued (e.g., that are not conflicted). Because the issuance is delayed, while determining whether a bank conflict exists, the efficiency of the cache is reduced, thereby resulting in less efficiency in the processor(s). That is, such inefficient utilization of the cache results in a net lower performance for a system's processor(s).

### BRIEF SUMMARY OF THE INVENTION

The present invention is directed to a system and method which enable resolution of conflicts between memory access requests in a manner that allows for efficient usage of cache memory. For example, in one embodiment, a circuit comprises a cache memory structure comprising multiple banks, and a plurality of access ports communicatively coupled to such cache memory structure. In such embodiment, the circuit further comprises circuitry operable to determine a bank conflict for pending access requests for the cache memory structure, and circuitry operable to issue at least one access request to the cache memory structure out of the order in which it was requested, responsive to determination of a bank conflict.

### BRIEF DESCRIPTION OF THE DRAWINGS

FIG. 1 shows a typical arrangement for a cache structure of the prior art;

FIG. 2A shows an exemplary in-order queue implementation of the prior art for holding peninding access requests and issuing such requests to the cache;

FIG. 2B shows an exemplary wave form of operation of a prior art system in issuing pending access requests in-order from the queue of FIG. 2A;

FIG. 3 shows the pipeline stages that may be implemented for a level of cache (e.g., L1 cache) of a preferred embodiment;

FIG. 4A shows an exemplary pending request queue for holding pending access requests for a level of cache in accordance with a preferred embodiment of the present invention;

FIG. 4B shows an exemplary wave form of operation of a preferred embodiment in issuing pending requests from the pending request queue of FIG. 4A;

FIG. 5 shows an exemplary logical diagram of a cache implementation for nominating and issuing memory access requests according to a preferred embodiment;

FIG. 6 shows an exemplary implementation of a preferred embodiment for generating an arbitration signal for a pending memory access request that indicates whether a conflict exists for such request such that the request should not be nominated for issuance;

FIGS. 7A-7B show an exemplary implementation of a preferred embodiment for determining whether a new entry being inserted into the queue is in conflict with an older pending entry or a sibling entry;

FIG. 8 shows an exemplary CAM array that is utilized in a preferred embodiment for detecting read entry versus store bank conflicts as well as read entry versus fill bank conflicts; and

FIG. 9 shows circuitry of a preferred embodiment for generating an arbitration signal for a pending memory access request that indicates whether a bank conflict exists for such entry.

### DETAILED DESCRIPTION OF THE INVENTION

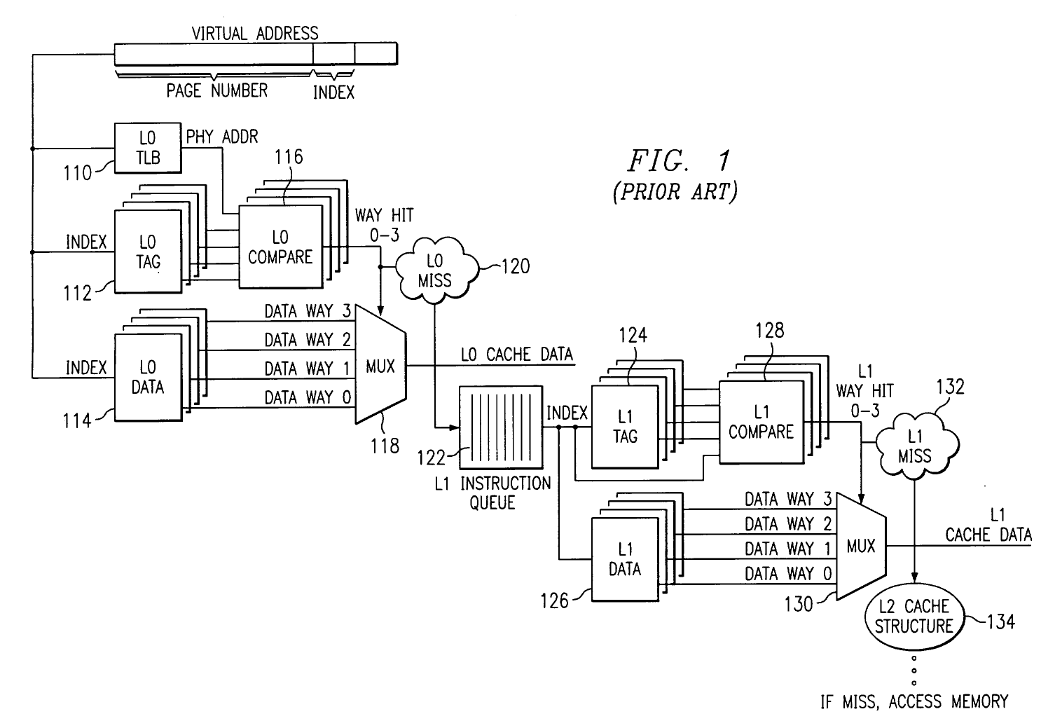

To provide the reader with a better appreciation of the description of embodiments of the present invention, further description of cache designs of the prior art are provided hereafter. An exemplary multi-level cache design of the prior art is shown in FIG. 1. The exemplary cache design of FIG. 1 has a three-level cache hierarchy, with the first level referred to as L0, the second level referred to as L1, and the third level referred to as L2. Accordingly, as used herein L0 refers to the first-level cache, L1 refers to the second-level cache, L2 refers to the third-level cache, and so on. It should be understood that prior art implementations of multi-level cache design may include more than three levels of cache, and prior art implementations having any number of cache levels are typically implemented in a serial manner as illustrated in FIG. 1.

As discussed more fully hereafter, multi-level caches of the prior art are generally designed such that a processor accesses each level of cache in series until the desired address is found. For example, when an instruction requires access to an address, the processor typically accesses the first-level cache L0 to try to satisfy the address request (i.e., to try to locate the desired address). If the address is not found in L0, the processor then accesses the second-level cache L1 to try to satisfy the address request. If the address is not found in L1, the processor proceeds to access each successive level of cache in a serial manner until the requested address is found, and if the requested address is not found in any of the cache levels, the processor then sends a request to the system's main memory to try to satisfy the request.

Typically, when an instruction requires access to a particular address, a virtual address is provided from the processor to the cache system. As is well-known in the art, such virtual address typically contains an index field and a virtual page number field. The virtual address is input into a translation look-aside buffer (“TLB”) 110 for the L0 cache. The TLB 110 provides a translation from a virtual address to a physical address. The virtual address index field is input into the L0 tag memory array(s) 112. As shown in FIG. 1, the L0 tag memory array 112 may be duplicated N times within the L0 cache for N “ways” of associativity. Such “ways” are well known in the art, and the term “way” is used herein consistent with its ordinary meaning as applied within the field to cache memory, generally referring to a partition of the lower-level cache that enables associativity. For example, the lower-level cache of a system may be partitioned into any number of ways. Lower-level caches are commonly partitioned into four ways. As shown in FIG. 1, the virtual address index is also input into the L0 data array structure(s) (or “memory structure(s)”) 114, which may also be duplicated N times for N ways of associativity. The L0 data array structure(s) 114 comprise the data stored within the L0 cache, which may be partitioned into several ways.

The L0 tag 112 outputs a physical address for each of the ways of associativity. That physical address is compared with the physical address output by the L0 TLB 1 10. These addresses are compared in compare circuit(s) 116, which may also be duplicated N times for N ways of associativity. The compare circuit(s) 116 generate a “hit” signal that indicates whether a match is made between the physical addresses. As used herein, a “hit” means that the data associated with the address being requested by an instruction is contained within a particular cache. As an example, suppose an instruction requests an address for a particular data labeled “A”. The data label “A” would be contained within the tag (e.g., the L0 tag 112) for the particular cache (e.g., the L0 cache), if any, that contains that particular data. That is, the tag for a cache level, such as the L0 tag 112, represents the data that is residing in the data array for that cache level. Therefore, the compare circuitry, such as compare circuitry 116, basically determines whether the incoming request for data “A” matches the tag information contained within a particular cache level's tag (e.g., the L0 tag 112). If a match is made, indicating that the particular cache level contains the data labeled “A,” then a hit is achieved for that particular cache level.

Typically, the compare circuit(s) 116 generate a single signal for each of the ways, resulting in N signals for N ways of associativity, wherein such signal indicates whether a hit was achieved for each way. The hit signals (i.e., “L0 way hits”) are used to select the data from the L0 data array(s) 114, typically through multiplexer (“MUX”) 118. As a result, MUX 118 provides the cache data from the L0 cache if a way hit is found in the L0 tags. If the signals generated from the compare circuitry 116 are all zeros, meaning that there are no hits within the L0 cache, then “miss” logic 120 is used to generate a L0 cache miss signal. Such L0 cache miss signal then triggers control to send the memory instruction to the L1 instruction queue 122, which queues (or holds) memory instructions that are waiting to access the L1 cache. Accordingly, if it is determined that the desired address is not contained within the L0 cache, a request for the desired address is then made in a serial fashion to the L1 cache.

In turn, the L1 instruction queue 122 feeds the physical address index field for the desired address into the L1 tag(s) 124, which may be duplicated N times for N ways of associativity. The physical address index is also input to the L1 data array(s) 126, which may also be duplicated N times for N ways of associativity. The L1 tag(s) 124 output a physical address for each of the ways of associativity to the L1 compare circuit(s) 128. The L1 compare circuit(s) 128 compare the physical address output by L1 tag(s) 124 with the physical address output by the L1 instruction queue 122. The L1 compare circuit(s) 128 generate an L1 hit signal(s) for each of the ways of associativity indicating whether a match between the physical addresses was made for any of the ways of L1. Such L1 hit signals are used to select the data from the L1 data array(s) 126 utilizing MUX 130. That is, based on the L1 hit signals input to MUX 130, MUX 130 outputs the appropriate L1 cache data from L1 data array(s) 126 if a hit was found in the L1 tag(s) 124. If the L1 way hits generated from the L1 compare circuitry 128 are all zeros, indicating that there was no hit generated in the L1 cache, then a miss signal is generated from the “miss” logic 132. Such a L1 cache miss signal generates a request for the desired address to the L2 cache structure 134, which is typically implemented in a similar fashion as discussed above for the L1 cache. Accordingly, if it is determined that the desired address is not contained within the L1 cache, a request for the desired address is then made in a serial fashion to the L2 cache. In the prior art, additional levels of hierarchy may be added after the L2 cache, as desired, in a similar manner as discussed above for levels L0 through L2 (i.e., in a manner such that the processor accesses each level of the cache in series, until an address is found in one of the levels of cache). Finally, if a hit is not achieved in the last level of cache (e.g., L2 of FIG. 1), then the memory request is sent to the processor system bus to access the main memory of the system.

More recently, a more efficient cache architecture that does not require such progression through the various levels of cache in a serial fashion has been developed, such as is disclosed in co-pending and commonly assigned U.S. patent application Ser. No. 09/501,396 entitled “METHOD AND SYSTEM FOR EARLY TAG ACCESSES FOR LOWER-LEVEL CACHES IN PARALLEL WITH FIRST-LEVEL CACHE” filed Feb. 9, 2000, and co-pending and commonly assigned U.S. patent application Ser. No. 09/507,546 entitled “SYSTEM AND METHOD UTILIZING SPECULATIVE CACHE ACCESS FOR IMPROVED PERFORMANCE” filed Feb. 18, 2000. It will be appreciated that embodiments of the present invention may be implemented within, as examples, a cache structure such as that of FIG. 1, or within more efficient cache structures such as those disclosed in co-pending U.S. Patent Applications “METHOD AND SYSTEM FOR EARLY TAG ACCESSES FOR LOWER-LEVEL CACHES IN PARALLEL WITH FIRST-LEVEL CACHE” and “SYSTEM AND METHOD UTILIZING SPECULATIVE CACHE ACCESS FOR IMPROVED PERFORMANCE.”

Caches may be partitioned into a plurality of different banks. Further, multiple ports may be implemented to enable multiple memory access requests to the cache simultaneously (i.e., in parallel). However, the potential exists in such multi-ported systems for conflicts (e.g., bank conflicts) to arise between pending memory access requests. Prior art methods for resolving conflicts between pending requests have generally resulted in inefficient use of the cache, thereby reducing the overall efficiency (and speed) of the processor(s). As one example, prior art implementations have typically not allowed for “out of order processing.” That is, prior art implementations typically utilize a FIFO queue for holding access requests, wherein requests are only issued in the order in which they were received (i.e., from oldest to newest). However, when a conflict, such as a bank conflict, is encountered between pending requests, such a rigid, in-order method of issuing requests may result in inefficiency within the cache.

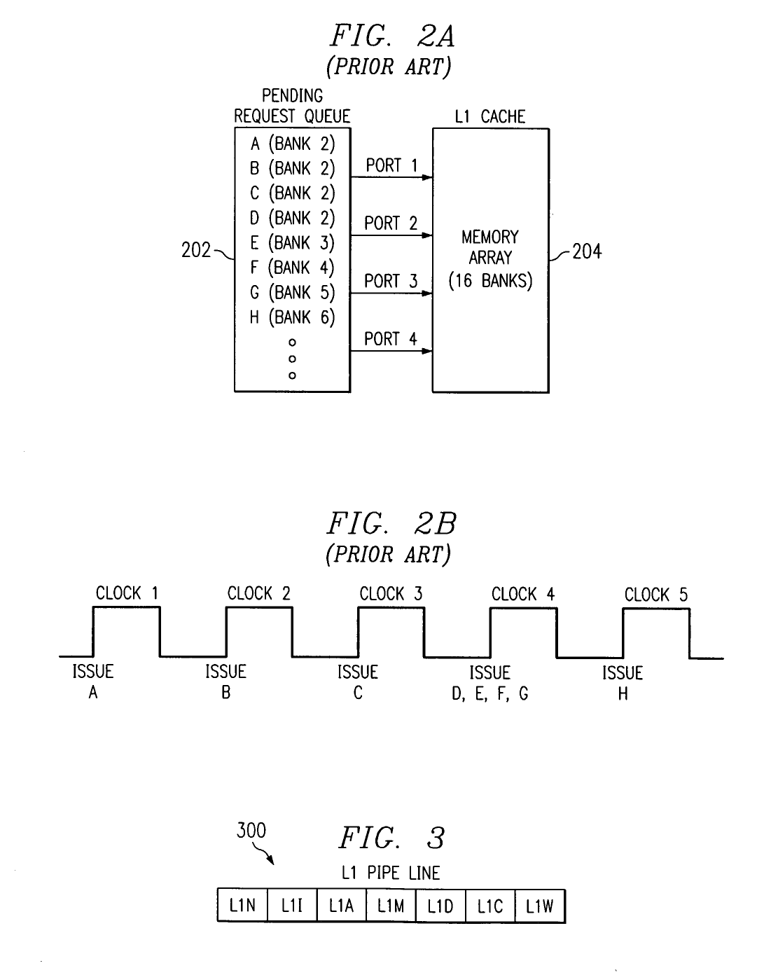

An example of such an in-order method of issuing requests is illustrated in FIGS. 2A-2B. FIG. 2A shows an exemplary queue 202 holding pending memory access requests A-H for the L1 cache memory array 204, which may include 16 banks of memory. In the example of FIG. 2A, four ports are implemented, which may be utilized to satisfy up to four memory access requests simultaneously (i.e., within the same clock cycle). In this example, requests A-H are received by queue 202 in order, such that A is the oldest pending request and H is the newest pending request. It should be noted that requests A-D all desire access to the same bank of the L1 cache, i.e., bank 2, and the remaining requests E-H each desire access to various other banks, i.e., banks 3-6 respectively.

Because a bank conflict exists between the access requests A-D, only one of such access requests can be issued at a time. Additionally, because queue 202 utilizes a rigid, in-order method of processing the requests, such conflict between requests A-D delays the issuance of the non-conflicted requests E-H. For instance, an exemplary wave form is included in FIG. 2B providing one example of how in-order queue 202 of FIG. 2A may issue the pending requests. As shown, only request A may be issued in the first clock cycle because the next oldest pending request (request B) is in conflict with request A and therefore cannot be issued. In the second clock cycle, only request B may be issued because the next oldest pending request (request C) is in conflict with request B and therefore cannot be issued. Likewise, in the third clock cycle, only request C may be issued because the next oldest pending request (request D) is in conflict with request C and therefore cannot be issued. Thus, while up to four requests can be issued simultaneously, only one request is issued in each of the first three clock cycles, even though non-conflicted requests (E-H) are pending in queue 202 during those cycles. In the fourth clock cycle requests D, E, F, and G may be issued simultaneously because such pending requests each desire access to a different bank of the L1 cache 204, and therefore are not in conflict with each other. In clock 5, request H is issued along with the next sequentially ordered requests that are not in conflict therewith.

Embodiments of the present invention enable efficient detection and resolution of memory access conflicts, thereby allowing pending memory access requests to be satisfied in an efficient manner. A preferred embodiment of the present invention provides a cache architecture that is implemented with a queue for holding pending access requests for a particular level of cache. For instance, one such queue may be implemented for the L1 cache, another for the L2 cache, and so on. Additionally, in a preferred embodiment, the cache is multi-ported to enable multiple access requests to be issued simultaneously each clock cycle. Furthermore, in a preferred embodiment the cache may include multiple banks. While the disclosed cache architecture of the present invention may be implemented for any level of cache, a preferred embodiment is described herein below with reference to level L1 of cache. Additionally, an exemplary implementation of a preferred embodiment is disclosed for a 256K-byte cache that includes 16 banks each having 128 indexes (essentially dividing each bank into 128 WORD lines), and the cache further includes four ports for satisfying memory access requests. It should be understood that such an implementation is intended solely as an example, to which the present invention is not intended to be limited, but instead the scope of the present invention is intended to encompass any cache implementation of any size, which may include any number of ports and banks.

For greater efficiency, the cache architecture is preferably implemented to enable levels thereof to be speculatively accessed as disclosed in co-pending and commonly assigned U.S. patent application Ser. No. 09/501,396 entitled “METHOD AND SYSTEM FOR EARLY TAG ACCESSES FOR LOWER-LEVEL CACHES IN PARALLEL WITH FIRST-LEVEL CACHE” filed Feb. 9, 2000, and co-pending and commonly assigned U.S. patent application Ser. No. 09/507,546 entitled “SYSTEM AND METHOD UTILIZING SPECULATIVE CACHE ACCESS FOR IMPROVED PERFORMANCE” filed Feb. 18, 2000. It should be understood, however, that embodiments of the present invention may be implemented in any suitable cache structure of the prior art, including cache structures that do not provide for speculative accessing of cache levels. Also, as further described hereafter, a preferred embodiment of the present invention enables out-of-order processing of access requests in the pending request queue.

In a preferred embodiment, a 64 bit virtual address (VA[63:0]) is received by the cache's TLB (e.g., TLB 10 of FIG. 1), and a 45 bit physical address (PA[44:0]) is output by the TLB. For instance, TLB 10 of FIG. 1 may be utilized to receive a virtual address (VA[63:0]) and translate such virtual address into a physical address (PA[44:0]). Although, some cache architectures may be implemented such that any number of bits may be utilized for the virtual address and physical address.

In most cache architectures, the lower address bits of the virtual address and the physical address match. In a preferred embodiment, the lower twelve bits of the virtual address (VA[11:0]) match the lower twelve bits of the physical address (PA[11:0]). Although, in alternative embodiments, any number of bits of the virtual address and physical address may match. Because the lower twelve bits of the virtual address and physical address match in a preferred embodiment, the TLB translates the non-matching bits of the virtual address (VA[63:12]) into the appropriate physical address PA[44:12]. That is, the TLB performs a look-up to determine the mapping for the received virtual address. Generally, there exists only one mapping in the TLB for the received virtual address. Because PA[11:0] corresponds to VA[11:0] and the TLB translates VA[63:12] into PA[44:12], the entire physical address PA[44:0] is determined once the TLB translates VA[63:12] into PA[44:12].

In one implementation of a preferred embodiment, a 256K-byte cache is implemented, which is banked into 16 banks having 128 indexes per bank. Of course, in alternative implementations, any size cache may be implemented. Additionally, in alternative implementations, any number of banks may be implemented for the cache. Generally, it is desirable to have the highest possible number of banks implemented for the cache.

In one implementation of a preferred embodiment, bits [14:8] of the physical address may be decoded to identify any of the 128 indexes of a bank. Also, in one implementation of a preferred embodiment, bits [7:4] of the physical address are decoded to select to which bank an access is to be issued, as is disclosed in greater detail in co-pending and commonly assigned U.S. patent application Ser. No. 09/507,546 entitled “SYSTEM AND METHOD UTILIZING SPECULATIVE CACHE ACCESS FOR IMPROVED PERFORMANCE” filed Feb. 18, 2000. Of course, in various alternative implementations different bits may be utilized for identifying a bank for an access request, and any such implementation is intended to be within the scope of the present invention.

Irrespective of the specific bits utilized for identifying a bank for an access request, such bits may be referred to broadly herein as “bank identifying bits”. Because in a preferred embodiment these bits of the physical address are known early (e.g., they are known when the virtual address is received), the bank to be accessed may be selected early (e.g., before the TLB decodes the remaining bits of the physical address). Additionally, such bank identifying bits may be utilized to efficiently determine whether bank conflicts exist, rather than attempting to determine whether a bank conflict exists at the time of issuing a memory access request from the queue of pending requests.

In a preferred embodiment, the pending request queue for the L1 cache may, each clock cycle, select up to four entries to be issued down the L1 pipeline. It should be understood that in implementations having greater than four ports, more than four entries may be issued down the L1 pipeline simultaneously. In preparation for issuing such entries, the entries capable of being issued in a given clock cycle (e.g., entries that are not in conflict with an older pending entry, etc.) are referred to as being “nominated”. In a preferred embodiment, the holding queue maintains a “head” indicating the beginning of the queue (i.e., the oldest pending entry) and a “tail” indicating the end of the queue (i.e., the newest pending entry). Once the nominated entries are determined, a selection process is initiated to determine the nominated entries to be issued (e.g., up to four in a four-ported cache), which determines the appropriate one (or more) of the nominated entries in the queue when searching from the head to the tail. While the holding queue may be implemented having any size, one implementation of a preferred embodiment utilizes a holding queue capable of holding up to 32 pending access requests. A preferred embodiment utilizes a pipeline approach for issuing pending requests from the queue, which is described in greater detail hereafter in conjunction with FIG. 3.

Various conflicts may exist between the pending access requests, thereby preventing one or more of such requests from being nominated for issuance. One type of conflict that may exist is a bank conflict. An example of a bank conflict that may be encountered is referred to as an “entry versus entry” bank conflict. In general, this is a conflict between two (or more) entries of the queue that each desire access to the same bank of the cache memory array during the same pipe stage. Another bank conflict that may be encountered is referred to as a “read entry versus fill” bank conflict. In general, this is a conflict between an entry in the pending request queue that desires to read from a bank during the same pipe stage that a “fill” operation (described further below) to the bank is desired. Another bank conflict that may be encountered is referred to as a “read entry versus store” bank conflict. In general, this is a conflict between an entry desiring to read from a bank during the same pipe stage that a store operation to the bank is desired. It will become more apparent through later description of the pipeline utilized for a preferred embodiment why such read and fill/store operations are conflicted from being performed within the same pipe stage. It should be understood that a “store” operation is where information is written into the cache array as a result of a store command or instruction, and a “fill” operation is where information is moved to the cache level from another portion of memory (e.g., moved up to the L1 cache from the L2 cache or moved down to the L1 cache from the L0 cache).

A preferred embodiment provides a system and method for determining/recognizing such bank conflicts and resolving them in a manner that enables efficient utilization of the cache. Of course, conflicts other than those described above may be encountered, and the cache architecture of a preferred embodiment may further be implemented to enable efficient recognition and resolution of any such conflicts. For example, “over subscription” (e.g., over subscription of integer resources and/or over subscription of floating point resources) is another type of conflict that may be encountered within the cache architecture. To enable efficient resolution/avoidance of such over subscription, a preferred embodiment may be implemented as disclosed in co-pending and commonly assigned U.S. patent application Ser. No. 09/510,973 entitled “MULTILEVEL CACHE STRUCTURE AND METHOD USING MULTIPLE ISSUE ALGORITHM WITH OVER SUBSCRIPTION AVOIDANCE FOR HIGH BANDWIDTH CACHE PIPELINE” filed Feb. 21, 2000.

FIG. 3 shows the pipeline stages that may be implemented for a level of cache (e.g., L1 cache) of a preferred embodiment. It should be understood that a pipeline having different stages may be implemented in alternative embodiments, and any pipeline having any arrangement of stages is intended to be within the scope of the present invention. As shown in the example of FIG. 3, pipeline 300 for L1 cache is a seven stage pipeline, which means that it takes seven clock cycles for operations to advance through the entire pipeline (i.e., a pipe stage is performed each clock cycle).

The first stage of pipeline 300 is L1N, which is the entry nominate stage. During the L1N stage, entries from the holding queue are nominated for issuance to the L1 cache array. The next stage is L1I, which is the entry issue stage. During the L1I stage, the appropriate entries are issued to the cache, wherein the data for the entry is driven out to the appropriate bank of the cache. As an example, in a four-ported cache, suppose seven pending entries are nominated in stage L1N, then up to four of such nominated entries may be selected for issuance in stage L1I. Generally, of the nominated requests, the oldest pending requests are selected for issuance ahead of newer pending requests. The next stage is L1A, which is the address and control information delivery stage. During the L1A stage the addresses to be accessed are driven out to the cache array.

The next stage of pipeline 300 is L1M, which is the L1 memory stage. During the L1M stage, a data load (or read) memory access request is performed. That is, the L1M pipe stage is utilized to read data from the cache. Thus, a read request nominated in stage L1N and issued in stage L1I is actually performed (i.e., actually accesses the appropriate address of the L1 cache) in stage L1M. The next stage is L1D, which is the data delivery stage. During the L1D pipe stage, the L1 cache drives the desired data back out to the consumers of the information (i.e., back to the requesting process). The following stage is L1C, which is the data correction stage. During the L1C pipe stage, errors in the data read from cache (e.g., if one of the bits was not read correctly) may be detected and corrected. The final pipe stage is L1W, which is the data write stage. During the L1W pipe stage, data is actually written to the L1 cache memory array (e.g., in order to satisfy a store or fill request). Thus, a write request (e.g., a store or fill request) nominated in L1N and issued in L1I is actually performed (i.e., actually accesses the appropriate address for writing to the L1 cache) in L1W. An important aspect of pipeline 300 to recognize is that read operations are performed in the L1M pipe stage, which occurs three clock cycles before the L1W pipe stage in which write operations (e.g., stores/fills) are performed. Thus, in certain embodiments of the present invention, a pipeline may be implemented in which certain memory access requests (e.g., reads) are performed in a particular pipe stage and other memory access requests (e.g., writes) are performed in a different pipe stage.

It should be understood that a preferred embodiment utilizes multiple ports (e.g., four ports) to enable multiple memory access requests to be satisfied (e.g., to be progressing along the same pipe stages) simultaneously (in parallel). Furthermore, it should be recognized that various access requests may be proceeding along the pipeline at different stages. For instance, one request may be at the L1W pipe stage, while other requests may be simultaneously at the L1C, L1D, L1M, L1A, L1I, and L1N pipe stages. Implementation and utilization of such a pipeline of operations is well known in the art, and therefore will not be described in greater detail herein.

It should be realized from pipeline 300 that an evaluation of the requests that have been issued (in L1I) must be made when nominating requests in L1N so as to avoid issuance of a read operation that will reach the L1M stage at the same time as a previously issued write request (for the same bank as the read operation) reaching the L1W stage. For example, suppose a write request (e.g., a store or a fill request) to a particular bank of cache level L1 is nominated in stage L1N in a first clock cycle (i.e., in “clock 1”) and issues in L1I the next clock cycle (i.e., in “clock 2”). Following the progression of such write request along pipeline 300, it will reach the L1M pipe stage in the fourth clock cycle (i.e., in “clock 4”) and will reach the L1W pipe stage in the seventh clock cycle (i.e., in “clock 7”), at which point it will actually be performed in the L1 cache as described above. Suppose further that during clock 4 (while the write request is in the L1M pipe stage), a request to read from the particular bank is pending in the queue. If such read request were nominated in L1N during clock 4 and issued in L1I in clock 5, such read request would reach the L1M pipe stage at the same time that the write request reaches L1W (i.e., in clock 7). It should be recalled that read operations are performed during the L1M pipe stage and write requests are performed during the L1W pipe stage. Accordingly, a request to read from a particular bank that reaches the L1M pipe stage simultaneously with a request to write to the particular bank reaching the L1W pipe stage results in a bank conflict between such requests.

Thus, to avoid such conflicting memory accesses from occurring, it is important that the issued requests progressing through the pipeline be evaluated before nominating/issuing a request that may conflict. More specifically, it is important that a record be maintained of the issued write requests (e.g., stores/fills) progressing through the pipeline to ensure that a read request is not nominated in the L1N pipe stage during a clock cycle that would result in such read request reaching the L1M pipe stage simultaneously with the write request to the same bank reaching the L1W pipe stage. Particularly, as described above, it is important to ensure that a read request to a particular bank is not nominated in L1N during a clock cycle in which an earlier issued write request to the particular bank is in the L1M pipe stage.

In a preferred embodiment, a conflict matrix is maintained for the pending request queue to indicate any conflicts that exist between pending entries (i.e., pending memory access requests) of the queue. More specifically, in a preferred embodiment, a 32 by 32 matrix of bank conflict bits is maintained within the queue's issue block. Such a matrix of bank conflicts keeps track of which memory access requests (or entries) in the queue are in conflict with some other memory access request (or entry) in the queue. The major axis of the matrix is permanently tied low such that an access request cannot have a bank conflict with itself. The remaining 31 bits of a column specifies whether or not the entry in that column has a bank conflict with any of the other entries in the queue. Preferably, the bank conflict bits are set for a memory access request upon insertion of such request into the pending request queue.

Preferably, the pending request queue for a level of cache is implemented with the capability of issuing pending access requests out of order. For instance, in contrast to the example shown in FIG. 2A, a preferred embodiment is implemented with the capability to issue requests A, E, F, and G in clock cycle 1, assuming that such requests are not otherwise conflicted. Thus, conflicts between older requests (e.g., between requests A-D of FIG. 2A) does not necessarily delay the issuance of non-conflicted newer requests (e.g., requests E-H of FIG. 2A). Examples of such out-of-order processing are further disclosed in co-pending and commonly assigned U.S. patent application Ser. No. 09/510,973 entitled “MULTILEVEL CACHE STRUCTURE AND METHOD USING MULTIPLE ISSUE ALGORITHM WITH OVER SUBSCRIPTION AVOIDANCE FOR HIGH BANDWIDTH CACHE PIPELINE” filed Feb. 21, 2000, co-pending and commonly assigned U.S. patent application Ser. No. 09/510,283 entitled “CACHE CHAIN STRUCTURE TO IMPLEMENT HIGH BANDWIDTH LOW LATENCY CACHE MEMORY SUBSYSTEM” filed Feb. 21, 2000, and co-pending and commonly assigned U.S. patent application Ser. No. 09/510,285 entitled “L1 CACHE MEMORY” filed Feb. 21, 2000.

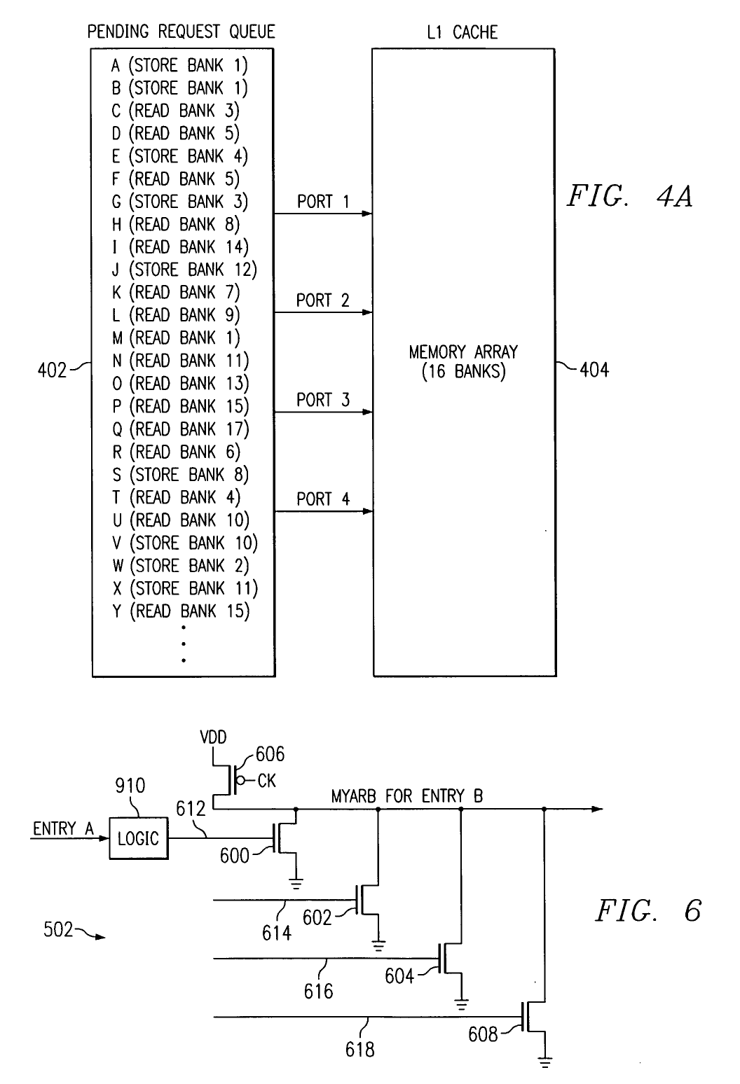

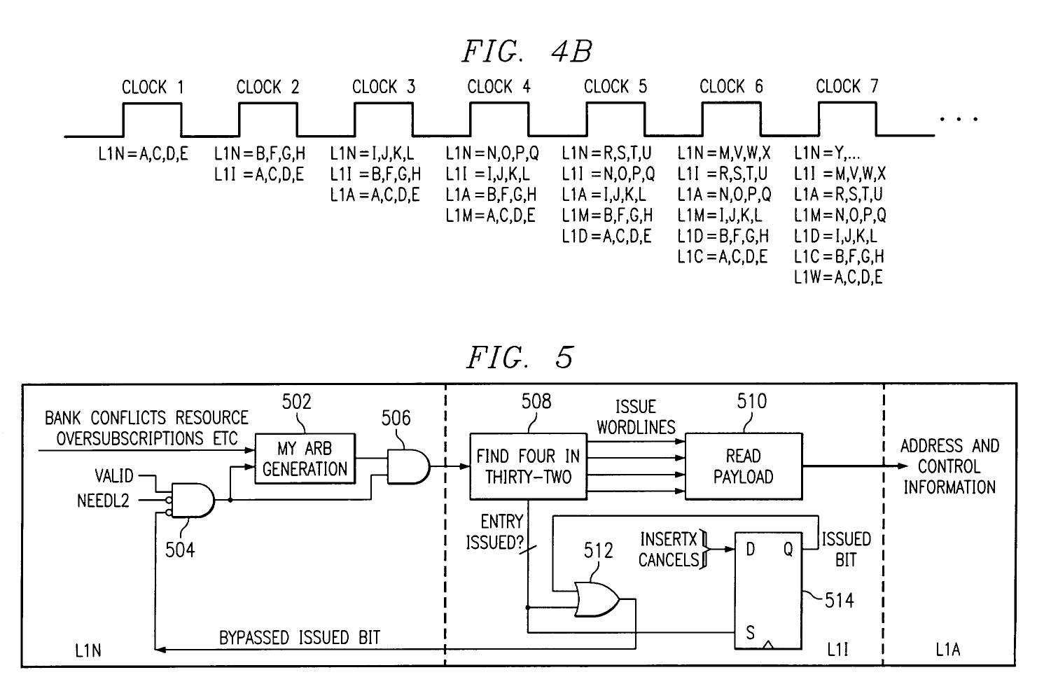

An example of such an out-of-order method of issuing requests in accordance with a preferred embodiment of the present invention is illustrated in FIGS. 4A-4B. FIG. 4A shows an exemplary queue 402 holding pending memory access requests A-Y for L1 cache memory array 404, which may, for example, include 16 banks of memory. In the example of FIG. 4A, four ports are implemented, which may be utilized to satisfy up to four memory access requests simultaneously (i.e., within the same clock cycle). In this example, requests A-Y are received by queue 402 in order, such that request A is the oldest pending request and request Y is the newest pending request.

FIG. 4B shows an exemplary wave form illustrating operation of a preferred embodiment in satisfying the pending requests A-Y of queue 402. In the first clock cycle (i.e., clock 1), up to four of the pending requests may be nominated for issuance. That is, up to four of the pending requests from queue 402 may be placed into the L1N pipe stage of exemplary pipeline 300 (FIG. 3) of a preferred embodiment. In general, operation of a preferred embodiment attempts to satisfy the oldest pending requests first. More specifically, each of the four oldest pending requests will be nominated, unless one of the requests conflicts with an older pending request. Thus, because requests A, B, C, and D are the oldest pending requests, they will be nominated unless a conflict exists. In this example, requests A and B each desire access to the same bank (i.e., bank 1) of the L1 cache, and are therefore in conflict. Accordingly, request B may not be nominated simultaneously with request A.

It should be recalled from the exemplary in-order processing method of the prior art described above with FIGS. 2A-2B, in such traditional in-order processing method only request A would be issued, as the conflict with request B effectively blocks any of the newer pending requests behind request B in the queue (e.g., requests C-Y) from being issued. As shown in FIG. 4B, a preferred embodiment of the present invention enables out-of-order processing. For example, in clock cycle 1, requests A, C, D, and E are nominated (placed into pipe stage L1N). Thus, request B is not nominated because of its conflict with older pending request A, but such conflict does not prevent non-conflicted requests C, D, and E from being nominated.

In clock cycle 2, requests A, C, D, and E advance to pipe stage L1I, and up to four more requests may be nominated (placed into stage L1). In clock cycle 2, request B is the oldest pending request, and is therefore nominated along with non-conflicted requests F, G, and H. In clock cycle 3, requests A, C, D, and E advance to pipe stage L1A, and requests B, F, G, and H advance to pipe stage L1I. Further, in clock cycle 3, the next pending requests I, J, K, and L, which are not in conflict, are nominated (placed into stage L1N).

In clock cycle 4, requests A, C, D, and E advance to pipe stage L1M, and each of the other requests in the pipeline advance forward one stage, as shown in FIG. 4B. At this point, the oldest pending request in queue 402 is request M, which is a request to read from bank 1 of L1 cache 404. It should be noted that request A in pipe stage L1M is a store request for bank 1 of L1 cache 404. Thus, a read entry versus store bank conflict is encountered between requests A and M. That is, if request M were nominated in clock cycle 4, while request A is in pipe stage L1M, request M would reach stage L1M to perform a read of bank 1 at the same time that request A reaches stage L1W to perform a store to bank 1. Accordingly, a preferred embodiment resolves such read entry versus store bank conflict by not nominating request M in clock cycle 4. However, because a preferred embodiment enables out-of-order processing, the next pending requests N, O, P, and Q, which do not have a conflict, are nominated (placed into stage L1N) in clock cycle 4, as shown in FIG. 4B.

In clock cycle 5, each of the requests in the pipeline advance forward one stage, and up to four new requests may be nominated (placed into stage L1N). In clock cycle 5, request M is again the oldest pending request in queue 402. It should be noted that request B, which is a store request for bank 1 of L1 cache 404, is now in pipe stage L1M. Thus, a read entry versus store bank conflict is encountered between requests B and M in clock cycle 5. That is, if request M were nominated in clock cycle 5, while request B is in pipe stage L1M, request M would reach stage L1M to perform a read of bank 1 at the same time that request B reaches stage L1W to perform a store to bank 1. Accordingly, a preferred embodiment resolves such read entry versus store bank conflict by not nominating request M in clock cycle 5. However, because a preferred embodiment enables out-of-order processing, the next pending requests R, S, T, and U, which do not have a conflict, are nominated (placed into stage L1N) in clock cycle 5, as shown in FIG. 4B.

In clock cycle 6, each of the requests in the pipeline advance forward one stage, and up to four new requests may be nominated (placed into stage L1N). In clock cycle 6, request M is again the oldest pending request in queue 402. A conflict does not exist for request M in clock cycle 6, and therefore request M is nominated (placed into stage L1N), along with the next oldest pending requests that are not in conflict, which are requests V, W, and X in this example.

In clock cycle 7, each of the requests in the pipeline advance forward one stage, and up to four new requests may be nominated (placed into stage L1N) from pending queue 402. At this point, requests A, C, D, and E reach pipe stage L1W, wherein requests A and E will be satisfied by performing stores to banks 1 and 4, respectively. Further, the next oldest pending requests in queue 402 that are not in conflict (e.g., requests y, . . . ) are nominated.

It should be recognized that such out-of-order processing presents the potential for certain hazards. For example, suppose an earlier pending store request is to store data to a particular address and a later pending read request is to read the data from the particular address. If care is not taken in the performance of the above-described out-of-order processing, potential exists for the later pending read request to be processed before the earlier pending store request, which may result in the read request reading outdated (or incorrect) data. A preferred embodiment guards against such hazards. More specifically, circuitry to guard against such hazards is preferably implemented outside of the pending request queue, such that if a hazard is detected for a request that was issued out of order, the guarding circuitry cancels the request and allows it to access the cache's data array only after the ordering hazard is no longer present.

In a preferred embodiment, a signal (or line) is utilized for each entry in the pending request queue that reflects whether a conflict exists for such entry. More specifically, a signal referred to herein as “myarb” (or as an “arbitration” signal) is generated for each entry in the pending request queue indicating whether such entry is conflicted in some manner that prevents such entry from being issued.

Turning to FIG. 5, an exemplary logical diagram of a cache implementation according to a preferred embodiment is shown. FIG. 5 illustrates the corresponding pipe stages (L1N and L1I) in which the logical components nominate and issue a memory access request in a preferred embodiment. It should be understood that certain bank conflicts, such as entry versus entry bank conflicts, may be determined early, rather than determining such conflict when attempting to issue requests. For instance, entry versus entry bank conflicts may be determined upon insertion of a request into the pending request queue. Certain bank conflicts may be determined for a pending request at the L1N stage (such that nomination of a conflicted request is avoided). For instance, read entry versus store bank conflicts and read entry versus fill bank conflicts may be determined for a request in the L1N pipe stage.

According to a preferred embodiment, data that is sufficient for determining which entries of the pending queue are ready to be nominated is input to logical AND gate 504. In this example, a VALID signal, NEEDL2 signal, and BYPASSED ISSUED BIT signal are input to AND gate 504. The VALID signal indicates whether the requested access is a valid access from the core pipeline. The NEEDL2 signal indicates whether the requested access missed (did not find the desired address) in level L1 of the cache, and therefore needs to access level L2. As described further below, the BYPASSED ISSUED BIT is output by OR gate 512 and indicates whether the requested access has already been issued to the data array of the cache.

While only shown for one entry of the pending request queue in FIG. 5, it should be recognized that such AND gate 504, as well as myarb generation circuitry 502 and AND gate 506, are preferably duplicated for each possible entry in the pending request queue. The output of AND gate 504 is input to the myarb generation circuitry 502, along with data identifying conflicts (e.g., bank conflicts, etc.), and circuitry 502 generates the myarb signals for each memory access request in the pending queue. Thus, myarb generation circuitry 502 receives input from which it may be determined whether a pending request in the pending queue is appropriate for nomination. Circuitry 502 generates a myarb signal for the entry that indicates whether the myarb signal is appropriate for nomination in the L1N pipe stage. Circuit block 502 for generating such a myarb signal for an entry in the pending queue is described in greater detail hereafter in conjunction with FIG. 6.

The myarb signal output by circuitry 502 and the output of AND gate 504 are input to the logical AND gate 506. Thus, the output of logical AND gate 506 identifies the set of entries in the queue that are ready to issue and do not have a conflict (e.g., bank conflict) with an older pending entry in the queue.

Circuit block 508 receives as input the output of logical AND gate 506, and circuit block 508 is utilized in pipe stage L1I to select up to four of the entries nominated in L1N for issuance, assuming that the cache is implemented as a four-ported cache. Once the appropriate one(s) of the nominated entries are selected for issuance, the WORD lines are fired for such selected entries. Circuit block 510 reads out the information necessary to perform the memory access request stored in the pending request queue. Logical or gate 512 is utilized to prevent a particular access request from issuing two clocks in a row. More specifically, as an access request is issued, or gate 512 signals that such access request entry is no longer ready to be issued. Circuit block 514 is utilized to remember that an access is currently issued in the pipeline and should therefore not be issued again.

One type of bank conflict that may be encountered is an entry versus entry conflict. As described hereafter, a preferred embodiment is implemented to efficiently resolve such entry versus entry bank conflicts. As described above, in a preferred embodiment a “myarb” signal is generated for each entry of the pending request queue to indicate whether such entry is conflicted with another entry. In a preferred embodiment, such myarb signal is generated for each entry of the pending request queue in block 502 of FIG. 5 in the L1N pipe stage. Block 502 of FIG. 5 is shown in greater detail in FIG. 6.

As shown in FIG. 6, a preferred embodiment utilizes a wired OR structure to generate the myarb signal for an entry (i.e., for entry “B” of the pending request queue in this example). More specifically, the myarb line for entry B of the queue has a P-Channel Field-Effect Transistor (“PFET”) 606 coupled to it, which precharges the myarb line to a high voltage level (i.e., to a logic 1) on the positive going clock transition (CK). That is, on clock CK, PFET 606 is turned on and precharges myarb to a high voltage level.

Additionally, multiple N-channel Field-Effect Transistors (“NFETs”) are coupled to the myarb line, such as NFETs 600, 602, 604, and 608. Such NFETs are dynamic circuits capable of pulling the myarb line for entry B to a low voltage level (i.e., to a logic 0) if the entry is conflicted with another entry in the pending request queue that prevents entry B from being issued. More specifically, the dynamic inputs 612, 614, 616, and 618 for NFETs 600, 602, 604, and 608 fire on the negative going clock transition (NCK), and if any one of such inputs cause their respective NFET to turn on at NCK (while PFET 606 is turned off), the myarb line for entry B will be pulled low. Inputs 612, 614, 616, and 618 to NFETs 600, 602, 604, and 608 cause their respective NFET to turn on if entry B is conflicted with an older pending entry in the pending request queue (i.e., entry B is conflicted with an entry that is ahead of it in the pending request queue).

In a preferred embodiment, such an entry versus entry bank conflict is detected for an entry upon its insertion to the pending request queue. That is, as a new entry for a memory access request is inserted to the pending request queue, a determination is made as to whether any older pending access requests already in the queue cause a bank conflict with this new entry, and if so, a bank conflict bit is set in the queue's conflict matrix for the new entry and its respective myarb line is pulled low.

For example, as shown in FIG. 6, suppose entry A, which is older than entry B, is ready to issue from the pending queue, and new entry B, which is bank conflicted with entry A, desires to issue at the same time as entry A (as in the example of clock cycle 1 of FIGS. 4A-4B). Assuming that entry A is actually a valid entry capable of being issued (i.e., it is not conflicted with an older pending request), then a mechanism within the bank conflict box inhibits request B from issuing, thereby enabling request A to be issued. In the example of FIG. 6, such mechanism that inhibits request B is NFET 600. More specifically, logic 910 (which is described in greater detail hereafter in conjunction with FIG. 9) outputs a signal that turns on NFET 600, which pulls down the myarb line for request B, thereby inhibiting request B from being issued.

In a preferred embodiment, multiple new entries may be simultaneously entered into the pending request queue. For instance, in one implementation of a preferred embodiment the cache is implemented as a four-ported cache, wherein up to four requests may be simultaneously inserted into the pending request queue. Therefore, in addition to determining whether a bank conflict exists between a new entry and existing entries in the pending request queue, it must also be determined whether a bank conflict exists between the various new entries being presented to the queue in the same clock cycle (which are referred to herein as “sibling requests”).

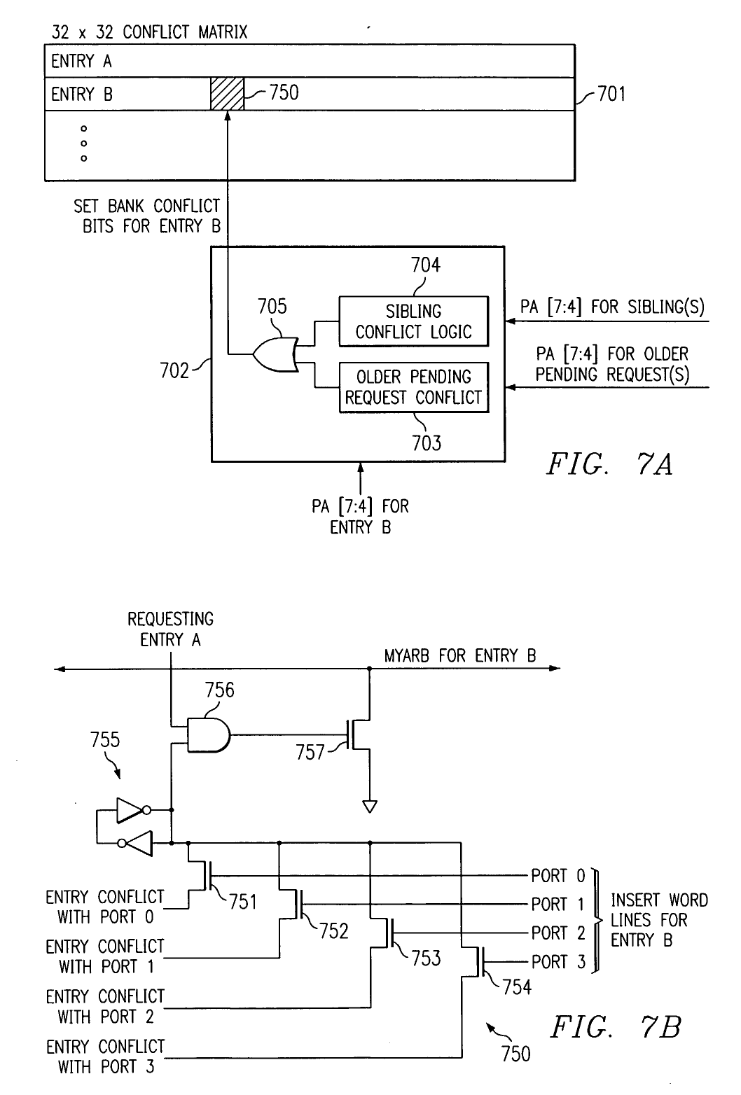

FIG. 7A shows a logical implementation of a preferred embodiment, which populates a conflict matrix 701 for entries pending in the pending request queue. Preferably, such conflict matrix is a 32×32 matrix with the diagonal of such matrix being unused (as an entry cannot conflict with itself). Upon insertion of an entry into the pending request queue, such entry is added to the conflict matrix and its corresponding conflict bits may be determined. For instance, in the example of FIG. 7A, an older pending entry A is already pending in the pending request queue when a new entry B is added thereto. Because the cache has four access ports in a preferred embodiment, up to three other “sibling” entries may be added to the pending request queue simultaneously with entry B. In the example of FIG. 7A, circuitry 702 is included to set the conflict bits for entry B in conflict matrix 701 upon entry B being inserted into the pending request queue for a level of cache. Circuitry 702 includes circuitry block 703 for detecting whether entry B is bank conflicted with an older pending request in the pending request queue. For instance, circuitry 703 may execute to compare PA[7:4] of entry B against PA[7:4] of the older pending requests to detect whether a bank conflict exists between entry B and any of such older pending requests, and if a bank conflict does exist, then the corresponding conflict bit for entry B may be set to indicate such a conflict.

Circuitry 702 further includes circuitry block 704 for detecting whether entry B is bank conflicted with a sibling entry being inserted into the pending request queue. For instance, circuitry 704 may execute to compare PA[7:4] of entry B against PA[7:4] of its sibling entry(ies) to detect whether a bank conflict exists between entry B and any of its sibling entries. If it is determined that a bank conflict does exist between entry B and one of its sibling entries, then the corresponding conflict bit for entry B may be set to indicate such a conflict with that sibling entry. Logical OR gate 705 is included such that a conflict bit for entry B is set to indicate a conflict with another entry if such other entry is an older pending request that is bank conflicted with entry B (as determined by circuit block 703) or if such other entry is a sibling entry that is bank conflicted with entry B (as determined by circuit block 704).

An exemplary implementation of a particular conflict bit 750 for entry B in conflict matrix 701 is shown in FIG. 7B. As shown, a storage cell 755 may be included for storing a conflict bit that indicates whether entry B is bank conflicted with another entry, such as entry A. In a preferred embodiment, the conflict bit circuitry 750 of FIG. 7B may be duplicated to provide 31 bits for entry B (it should be recalled that matrix 701 is 32×32 and an entry cannot conflict with itself), thereby indicating whether entry B is in conflict with any of up to 31 other entries included in conflict matrix 701. As shown in FIG. 7B, NFETs 751, 752, 753, and 754 may be included to indicate whether a bank conflict exists between entry B and a sibling entry being inserted to the pending request queue via another one of access ports 0-3. If such a bank conflict does exist between entry B and a sibling entry on another access port, then the bit in storage cell 755 is set to reflect such a sibling bank conflict. Logical AND gate 756 is included to output whether entry B is bank conflicted with an older pending entry or a sibling entry. For instance, in the example of FIG. 7B, the bit from storage cell 755, which indicates whether a sibling bank conflict exists, is input to AND gate 756 along with a signal that indicates whether entry B is conflicted with an older pending entry A. If entry B is bank conflicted with either a sibling entry or an older pending entry A, the output of AND gate 756 causes NFET 757 to turn on, which pulls the myarb line for entry B to a low voltage, thereby preventing entry B from being nominated for issuance to the cache.

It should be recognized that determining an entry versus entry bank conflict upon an entry's insertion into the pending queue in a preferred embodiment is particularly advantageous in that it enables much greater efficiency within the cache. Prior art cache architectures typically determine whether such a bank conflict exists when attempting to issue requests. For instance, in the above example, a typical cache architecture of the prior art would calculate whether a conflict exists between entry A and entry B on the actual issue. As a result, additional time is required for such calculation before the issuance of the entries can actually occur. Therefore, such a prior art cache architecture is less efficient than a preferred embodiment of the present invention, in which such entry versus entry bank conflicts are determined before the actual issuance (i.e., is determined upon insertion of an entry into the pending request queue). Accordingly, a preferred embodiment enables requests to be issued faster, which results in more efficient usage of cache (e.g., results in a higher bandwidth through the cache), and effectively makes the cache appear larger in size.

Another type of bank conflict that may be encountered is a read entry versus store bank conflict. A review of the L1 pipeline (as shown in FIG. 3) reveals that a read in the L1M pipe stage requiring access to the same bank as a write in the L1W pipe stage must not be allowed, in a preferred embodiment. As described hereafter, a preferred embodiment keeps track of the memory accesses that have been issued into the pipeline, and such accesses existing in the pipeline are compared against the pending entries in the pending request queue to determine the appropriate entries to nominate in the L1N pipe stage. More specifically, a preferred embodiment utilizes a Content Adjustable Memory (CAM) array structure to determine whether pending store entries in the pipeline are in conflict with any of the pending entries in the pending request queue. Implementation of a CAM array structure is well known in the art, and therefore will not be described in great detail herein.

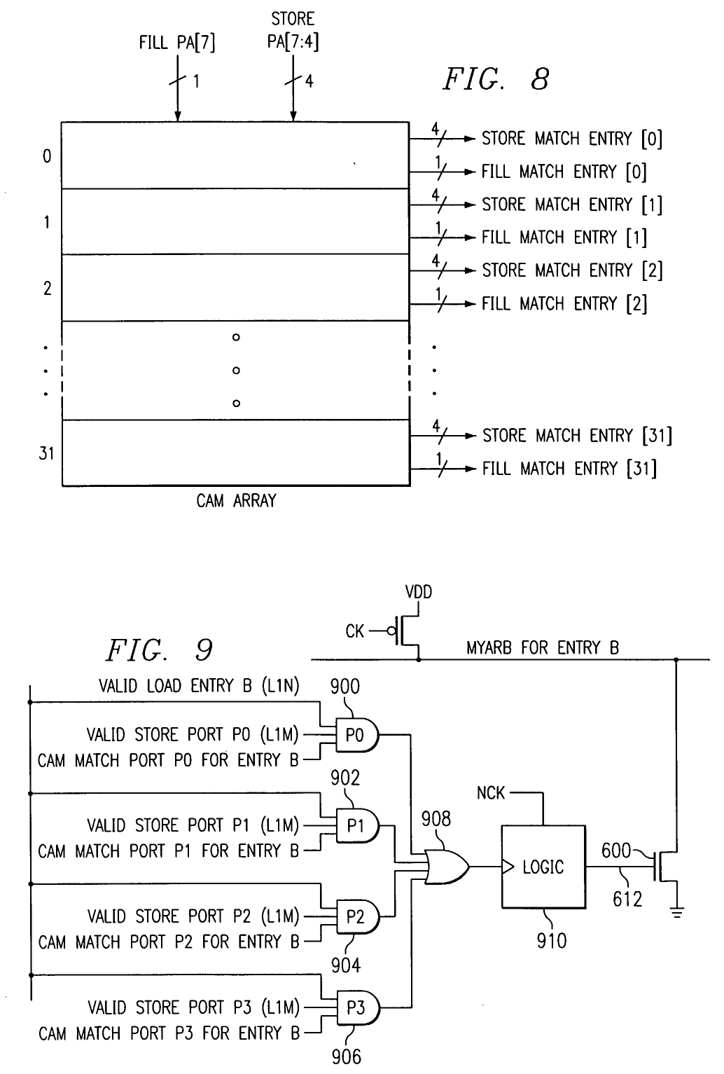

Turning to FIG. 8, an exemplary CAM array that is utilized in a preferred embodiment for detecting read entry versus store bank conflicts (as well as read entry versus fill bank conflicts, as described hereafter) is shown. As shown, in a preferred embodiment, the CAM array is a five-ported structure, which utilizes four ports for determining read entry versus store bank conflicts and utilizes the fifth port for determining read entry versus fill bank conflicts (as described in greater detail hereafter). While such a CAM array may be implemented having any number of entries, a preferred embodiment utilizes a 32-entry CAM array (e.g., having entries 0-31). Each entry of the CAM array comprises bank identifying bits (e.g., PA[7:4] in one implementation of a preferred embodiment) of a pending memory access request in the pending request queue. Preferably, extra bits are stored in the pending request queue for each pending entry that identify the type of memory access desired by such pending entry (e.g., whether a store, fill, or a read operation is desired).

Because a preferred embodiment may utilize a four-ported cache structure, up to four store operations may be performed during any given clock cycle. Accordingly, four ports are utilized in the CAM array of FIG. 8 for stores to enable up to four stores that have been issued into the pipeline to be compared against the access requests pending in the queue in order to prevent a read request pending in the queue from being nominated in L1N during a clock cycle when a conflicting store request is in the L1M pipe stage. If such nomination were not prevented and the read request were actually issued in the following L1I stage, a memory access conflict would occur when the read request reaches the L1M pipe stage simultaneously with the store request reaching the L1W pipe stage, as described above.

More specifically, in a preferred embodiment, the bank identifying bits (e.g., PA[7:4]) for a store request in the L1M pipe stage are cammed against the bank identifying bits for the read entries pending in the queue. As also shown in FIG. 8, a “Store Match” line is generated for each entry in the CAM array. Generally, a CAM array is implemented such that a “Match” line is initialized to a high voltage level (i.e., to a logic 1), and if a match is made between a value being input to the CAM and an entry in the CAM then the Match line remains high for the matching entry, otherwise the Match line for the entry is pulled to a low voltage level (i.e., to a logic 0) to indicate that a match was not made. Thus, for each read entry in the CAM array having bank identifying bits that correspond to those of the store(s) already in the L1M pipe stage, the corresponding Store Match line indicates such a match (e.g., by remaining high). In response to the Store Match line for an entry indicating that a match was achieved, the entry is made to fail arbitration (i.e., its myarb line is pulled low) to prevent the entry from being nominated in the L1N pipe stage during the clock cycle in which the conflicting store is in the L1M pipe stage.

Another type of bank conflict that may be encountered is a read entry versus fill bank conflict. In general, a “fill” operation is where information is moved to the cache level from another portion of memory (e.g., moved up to the L1 cache from the L2 cache or moved down to the L1 cache from the L0 cache). Typically, a fill request is not queued in the pending request queue, but is instead issued as needed. As described above, a fill may require multiple banks (e.g., eight banks), and therefore care must be taken to ensure that a read request for any of the banks required for the fill is not nominated during the same clock cycle during which such fill is in the L1M pipe stage. Much as described above for read entry versus store bank conflicts, a preferred embodiment keeps track of the fill requests that have been issued into the pipeline, and such fill requests existing in the pipeline are compared against the pending entries in the queue to determine the appropriate entries to nominate in the L1N pipe stage. More specifically, a preferred embodiment utilizes the CAM array structure of FIG. 8 to determine whether fill entries pending in the pipeline are in conflict with pending read entries for one of the banks being utilized for the fill request.

As shown in FIG. 8, one port of the five-ported CAM array is utilized in a preferred embodiment for detecting read entry versus fill bank conflicts. As described above, each entry of the CAM array comprises bank identifying bits (e.g., PA[7:4] in one implementation of a preferred embodiment) of a pending memory access request. Because a preferred embodiment may utilize multiple banks (e.g., eight banks) for performing a fill operation, such banks are compared with the banks of the pending read entries existing in the CAM array to determine whether a Fill Match is achieved for one or more of the entries. More specifically, in a preferred embodiment, the fill bank identifying bit(s) (e.g., PA[7]) in the L1M pipe stage is cammed against the corresponding bank identifying bit(s) (e.g., PA[7]) for the read entries pending in the queue. Because a preferred embodiment may utilize eight banks for a fill operation, only a comparison of PA[7] of the fill request and the pending read requests are required to be compared to generate the appropriate “Store Match” lines for each entry in the CAM array. For each read entry in the CAM array having bank identifying bit PA[7] that corresponds to the fill bank identifying bit PA[7] of the fill already in the L1M pipe stage, the corresponding Fill Match line indicates such a match (e.g., by remaining high). In response to the Fill Match line for an entry indicating that a match was achieved, the entry is made to fail arbitration (i.e., its myarb line is pulled low) to prevent the entry from being nominated in the L1N pipe stage during the clock cycle in which the conflicting fill is in the L1M pipe stage.

Turning now to FIG. 9, an exemplary implementation for generating a myarb signal for an entry according to a preferred embodiment is shown. More specifically, the exemplary implementation of FIG. 6 is shown in greater detail, wherein (as discussed above with FIG. 6) NFET 600 is utilized to pull the myarb signal for entry B low if a conflict is detected between entry B and entry A that prevents entry B from being nominated for issuance. Furthermore, as described hereafter, circuitry is included to pull the myarb signal for entry B low if entry B is a read entry (read request) in conflict with a store (i.e., is a read entry versus store bank conflict), thereby preventing entry B from being nominated for issuance.

In a preferred embodiment, the cache is implemented as a four-ported cache, and therefore in FIG. 9 four AND gates 900, 902, 904, and 906 are implemented. That is, AND gates 900, 902, 904, and 906 are implemented for operations being performed on ports P0, P1, P2, and P3, respectively. As shown, a signal “Valid Load Entry B (L1N)” is input to each of the four AND gates. This signal indicates whether entry B is a valid read (or “load”). That is, this signal indicates whether request B, which is pending in the queue in the L1N pipe stage, is a valid read (e.g., is not bank conflicted with an older pending request in such queue). Such signal may be obtained, for example, from the corresponding entry for request B in the conflict matrix, which indicates whether request B is bank conflicted with any other older pending request in the pending queue.

A separate signal is input to the corresponding AND gate for each port that indicates whether a store request is currently in the L1M pipe stage for such port. For example, signal “Valid Sotre Port P0 (L1M)” is input to AND gate 900 to indicate whether a store request currently exists in the L1M pipe stage for P0. As shown in FIG. 9, like signals for ports 1-3 are input to their respective AND gates 902, 904, and 906.

A third signal is input to the corresponding AND gate for each port that indicates whether the bank to be accessed for the entry B read request and the bank for a store request in the L1M pipe stage of such port match. For example, signal “CAM Match Port P0 for Entry B” is input to AND gate 800 to indicate whether the bank for a read request for entry B matches a store request currently in the L1M pipe stage of port P0. More specifically, the “CAM Match Port P0 for Entry B” signal indicates whether a match was made between the bank to be accessed by a store request in the L1M pipe stage of port P0 and the bank to be accessed by a read entry B, as indicated by the CAM array described above in FIG. 8. As shown in FIG. 9, like signals for ports 1-3 are input to their respective AND gates 902, 904, and 906.

Accordingly, the output from each AND gate 900, 902, 904, and 906 is a signal indicating whether it is appropriate to nominate entry B for the respective ports. For instance, the output from AND gates 900, 902, 904, and 906 indicates whether a bank conflict exists for entry B (e.g., whether a read entry versus store bank conflict and/or entry versus entry bank conflict exists for entry B). The output signals of the AND gates 900, 902, 904, and 906 are input to OR gate 908. Accordingly, the output of OR gate 908 indicates whether a bank conflict exists for either of the ports P0, P1, P2, or P3 for entry B. The output of OR gate 908 is input to dynamic logic 910, which dynamically generates a signal 612 for controlling NFET 600 in order to pull the myarb signal for entry B low if necessary (e.g., if a bank conflict exists such that entry B should be prevented from being nominated). For example, if a read entry versus store conflict is detected for entry B, logic 910 dynamically generates a high signal 612 that causes NFET 600 to turn on in order to pull the myarb signal for entry B low.

In view of the above, a preferred embodiment of the present invention enables efficient detection and resolution of memory access conflicts, such as bank conflicts for cache memory. A preferred embodiment allows for out-of-order processing of pending memory access requests to allow for more efficient use of the cache memory structure in satisfying access requests when a bank conflict is encountered for a pending request. A preferred embodiment also allows for early detection of entry versus entry bank conflicts. For instance, such entry versus entry bank conflicts may be determined for an entry upon its insertion into the pending request queue for a level of cache, rather than determining whether such a bank conflict exists at the time of attempting to issue the conflicted requests.

What is claimed is:

1. A circuit comprising:
cache memory structure comprising multiple banks;
a plurality of access ports communicatively coupled to said cache memory structure;
circuitry operable to determine a bank conflict for pending access requests for said cache memory structure; and
circuitry operable to issue at least one access request to said cache memory structure out of the order in which it was requested, responsive to determination of said bank conflict.

2. The circuit of claim 1 wherein said bank conflict comprises a bank conflict between at least two access requests.

3. The circuit of claim 1 further comprising:
pending request queue to which said pending access requests for said cache memory structure are stored, wherein said bank conflict is determined for at least one pending access request upon entry of said at least one pending access request into said pending request queue.

4. The circuit of claim 3 wherein said bank conflict comprises a bank conflict between at least one pending access request and least one issued access request.

5. The circuit of claim 1 wherein said circuitry operable to issue at least one access request is further operable to issue said at least one access request according to a predefined pipeline, said predefined pipeline having a plurality of stages with one stage for performing a first type of access and a different stage for performing a second type of access.

6. The circuit of claim 5 wherein said bank conflict comprises a bank conflict between at least one access request of said first type with at least one access request of said second type.

7. The circuit of claim 5 wherein said first type of access request comprises a request for a data store operation to a particular bank of said cache memory structure, and wherein said second type of access request comprises a request for a data read operation to said particular bank of said cache memory structure.

8. The circuit of claim 5 wherein said pipeline comprises:
a stage for nominating non-conflicted access requests for issuance to said memory cache structure; and
another stage for issuing to said cache memory structure at least one nominated request.

9. The circuit of claim 1 wherein said bank conflict comprises a bank conflict between at least one of said pending access requests and an older access request.

10. The circuit of claim 1 further comprising:
pending request queue to which said pending access requests for said cache memory structure are stored, wherein said bank conflict comprises a bank conflict between sibling access requests that are inserted to said pending request queue in parallel and wherein said bank conflict between sibling access requests is determined upon entry of said sibling access requests into said pending request queue.

11. A method for resolving bank conflicts between access requests for a cache memory structure that comprises a plurality of address banks, said method comprising:
storing access requests for said cache memory structure to a pending request queue;
determining at least one access request in said pending request queue that has a bank conflict;
determining at least one access request in said pending request queue that does not have a bank conflict, wherein said determined at least one access request that does not have a bank conflict is newer than the determined access request that has a bank conflict; and
nominating at least the determined access request that does not have a bank conflict for issuance to said cache memory structure.

12. The method of claim 11 wherein said cache memory structure comprises a plurality of access ports, said method further comprising:
nominating a plurality of access requests that do not have bank conflicts for issuance to said cache memory structure.

13. The method of claim 12 further comprising:
issuing a plurality of nominated access requests to said cache memory structure in parallel via said plurality of access ports.

14. The method of claim 11 further comprising:
performing said step of determining at least one access request that has a bank conflict upon entry of said at least one access request that has a bank conflict to said pending request queue.

15. The method of claim 11 wherein said bank conflict comprises a bank conflict with an older request pending in said pending request queue.

16. The method of claim 11 wherein said at least one access request requests a first type of access, and wherein said bank conflict comprises a bank conflict between said at least one access request and at least one other access request requesting a different type of access.

17. The circuit of claim 16 further comprising:
issuing said at least one access request that does not have a bank conflict according to a predefined pipeline, said predefined pipeline having a plurality of stages with one stage for performing said first type of access and a different stage for performing said different type of access.

18. The circuit of claim 17 wherein said first type of access comprises a load from said cache memory structure, and wherein said different type of access comprises a store to said cache memory structure.

19. A computer system comprising:
memory structure comprising a plurality of address banks;
means for queuing access requests for said cache memory structure;
means for determining whether a bank conflict exists for a pending access request; and
means for nominating at least one pending access request for issuance to said cache memory structure, wherein responsive to said determining means determining that a bank conflict exists for a pending access request, said nominating means nominating at least one pending access request out of the order in which it was queued in said queuing means.

20. The computer system of claim B I further comprising:
a plurality of access ports to said cache memory structure; and
means for issuing a plurality of nominated access requests to said cache memory structure in parallel via said plurality of access ports.
